(19) United States
(12) Patent Application Publication
(10) Pub. No.: US 2025/0287687 A1
(43) Pub. Date: Sep. 11, 2025

(54) SEMICONDUCTOR DEVICE AND METHODS FOR FORMING THE SAME

(71) Applicant: Vanguard International Semiconductor Corporation, Hsinchu (TW)

(72) Inventors: Chen-Dong TZOU, Taipei City (TW); Chia-Hao LEE, Zhubei City (TW)

(73) Assignee: Vanguard International Semiconductor Corporation, Hsinchu (TW)

(21) Appl. No.: 18/597,567

(22) Filed: Mar. 6, 2024

(51) Int. Cl. H01L 27/092; H01L 29/06; H01L 29/10; H01L 29/66; H01L 29/78

(52) U.S. Cl. CPC H10D 84/85; H10D 30/0291; H10D 30/668; H10D 62/10; H10D 62/393

(57) ABSTRACT

A semiconductor device includes a substrate that has a first conductivity type, an epitaxial layer on the substrate, a first device and a second device. The first device includes a first trench gate structure and a first shielding portion. The substrate functions as the drain of the first device. The second device that is electrically connected to the first device includes a second trench gate structure, a planar gate structure and a second shielding portion. The first and second trench gate structures extend downward from the top surface of the epitaxial layer into the epitaxial layer. The planar gate structure is disposed over the top surface of the epitaxial layer. The first and second shielding portions are in contact with the bottoms of the first and second trench gate structures, respectively. The first shielding portion and the second shielding portion have the second conductivity type.

### BACKGROUND

### Technical Field

The disclosure relates to a semiconductor device and methods for forming the same, and, in particular, to a semiconductor device that includes devices with different flow directions of driving currents on the same substrate and methods for forming the same.

### Description of the Related Art

The integration density of different electronic components is being continuously improved in the semiconductor industry. Continuously decreasing the minimum size of components allows more and more components to be integrated into a given area. For example, trench gate metal-oxide-semiconductor field effect transistors are designed to have a vertical structure to reduce the cell pitch and increase their functional density. In a trench gate metal-oxide-semiconductor field effect transistor (MOSFET), the back of the chip serves as a drain, while the sources and gates of various transistors are formed on the front of the chip. Accordingly, the flow of the driving current of a planar semiconductor device is in the horizontal direction, while the flow of the driving current of a trench gate semiconductor device is in the vertical direction, so that the trench gate semiconductor device can achieve a high withstand voltage and a low on-resistance. Thus, trench gate MOSFETs are widely applied in power switch components.

As the requirements for the electrical performance of semiconductor devices continuously increases, the types and functions of the integrated devices of semiconductor devices must also increase to meet these requirements in application. For example, devices with different current driving methods, such as a driving device having a driving current that flows in the horizontal direction (which can also be referred to as the planar direction) and a VDMOS device having a driving current that flows in the vertical direction, can be integrated in a package. The electrical devices are electrically connected by wire bonding or trace connection in the package structure to achieve the integration of electrical devices. However, these additional wires or traces will cause parasitic inductance between the driving device and the VDMOS device in the package structure. If the parasitic inductance is too high, the entire circuit or system cannot be operated at high frequencies. Therefore, although existing semiconductor devices and methods for forming the same have generally been adequate for their intended purposes, they have not been entirely satisfactory in all respects.

### BRIEF SUMMARY

Some embodiments of the present disclosure provide semiconductor devices. A semiconductor device of the embodiments includes several metal-oxide-semiconductor (MOS) devices that are integrated on the same substrate, and those MOS devices may have different flow directions of driving currents. A semiconductor device includes a substrate that has the first conductivity type, an epitaxial layer on the substrate, a first device and a second device. The epitaxial layer has the first conductivity type. The second device is separated from the first device and electrically connected to the first device. The first device includes a first trench gate structure and a first shielding portion. The first trench gate structure extends downward from the top surface of the epitaxial layer into the epitaxial layer. In some embodiments, the substrate functions as the drain region of the first device. The first shielding portion is positioned below the first trench gate structure and in contact with the bottom portion of the first trench gate structure. The first shielding portion has the second conductivity type. The second device includes a second trench gate structure, a planar gate structure and a second shielding portion. The second trench gate structure extends downward from the top surface of the epitaxial layer into the epitaxial layer. The planar gate structure is formed over the top surface of the epitaxial layer. The second shielding portion is positioned under the second trench gate structure and in contact with the bottom portion of the second trench gate structure. The second shielding portion has the second conductivity type.

Some embodiments of the present disclosure provide methods for forming a semiconductor device. A method for forming a semiconductor device includes providing a substrate that has a first conductivity type, and forming an epitaxial layer on the substrate. The epitaxial layer has the first conductivity type. The method for forming the semiconductor device further includes forming a first device in a first region of the epitaxial layer and forming a second device in a second region of the epitaxial layer. The second device is separated from the first device and electrically connected to the first device. The first device includes a first trench gate structure and a first shielding portion. The first trench gate structure extends downward from the top surface of the epitaxial layer into the epitaxial layer. In some embodiments, the substrate functions as a drain region for the first device. The first shielding portion is positioned below the first trench gate structure and in contact with the bottom portion of the first trench gate structure. The first shielding portion has the second conductivity type. The second device includes a second trench gate structure, a planar gate structure and a second shielding portion. The second trench gate structure extends downward from the top surface of the epitaxial layer into the epitaxial layer. The planar gate structure is formed over the top surface of the epitaxial layer. The second shielding portion is positioned under the second trench gate structure and in contact with the bottom portion of the second trench gate structure. The second shielding portion has the second conductivity type.

### BRIEF DESCRIPTION OF THE DRAWINGS

The present invention can be more fully understood by reading the subsequent detailed description and examples with references made to the accompanying drawings, wherein:

FIG. 1, FIG. 2, FIG. 3, FIG. 4, FIG. 5, FIG. 6, FIG. 7, FIG. 8, FIG. 9 and FIG. 10 illustrate cross-sectional views of intermediate stages of a method for forming a semiconductor device, in accordance with some embodiments of the present disclosure.

### DETAILED DESCRIPTION OF THE INVENTION

The following description provides various embodiments, or examples, for implementing different features of the present disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numbers and/or letters in the various examples. This repetition is for the purpose of simplicity and clarity and does not in itself dictate a relationship between the various embodiments and/or configurations discussed.

In addition, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly.

Some embodiments are described below. Throughout the various views and illustrative embodiments, similar reference numbers are used to designate similar features/components. It should be understood that additional operations can be provided before, during, and after the method, and some of the operations can be replaced or eliminated for other embodiments of the method.

Embodiments provide semiconductor devices and methods for forming the same. In some embodiments, a semiconductor device is formed by integrating the metal-oxide-semiconductor (MOS) devices that are disposed on the same substrate, and these MOS devices have different flow directions of driving currents. In some exemplary embodiments, a complementary metal-oxide-semiconductor (CMOS) device that has a driving current flowing in the horizontal direction and a vertical-diffused metal-oxide-semiconductor (VDMOS) device that has a driving current flowing in the vertical direction are integrated on a substrate to form a semiconductor device. In addition, the CMOS device and the VDMOS device that are disposed on the same substrate have trench gates, in accordance with some embodiments of the present disclosure.

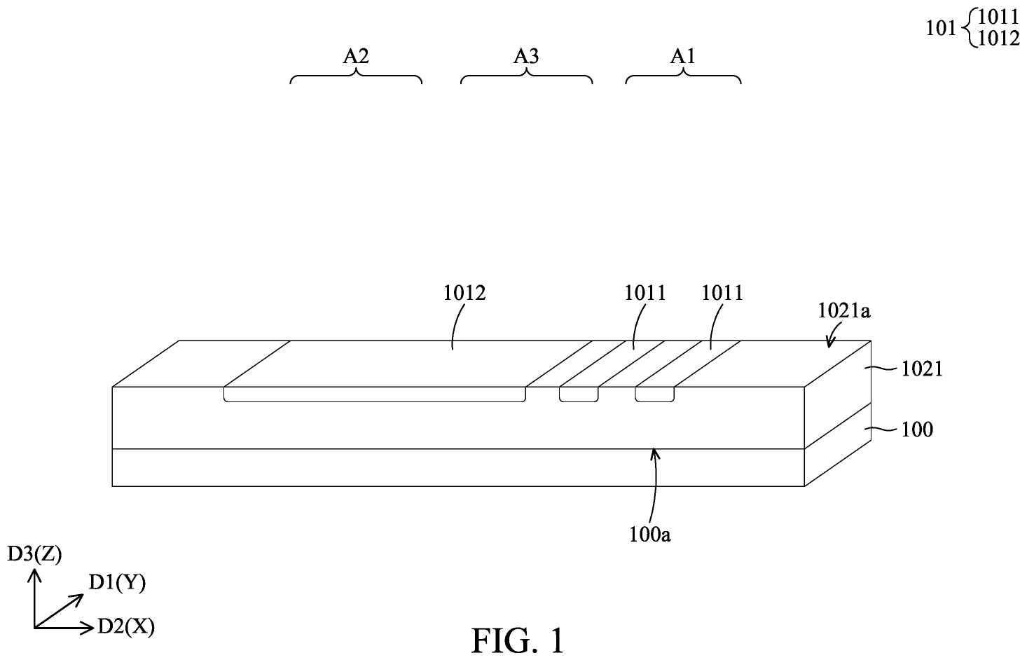

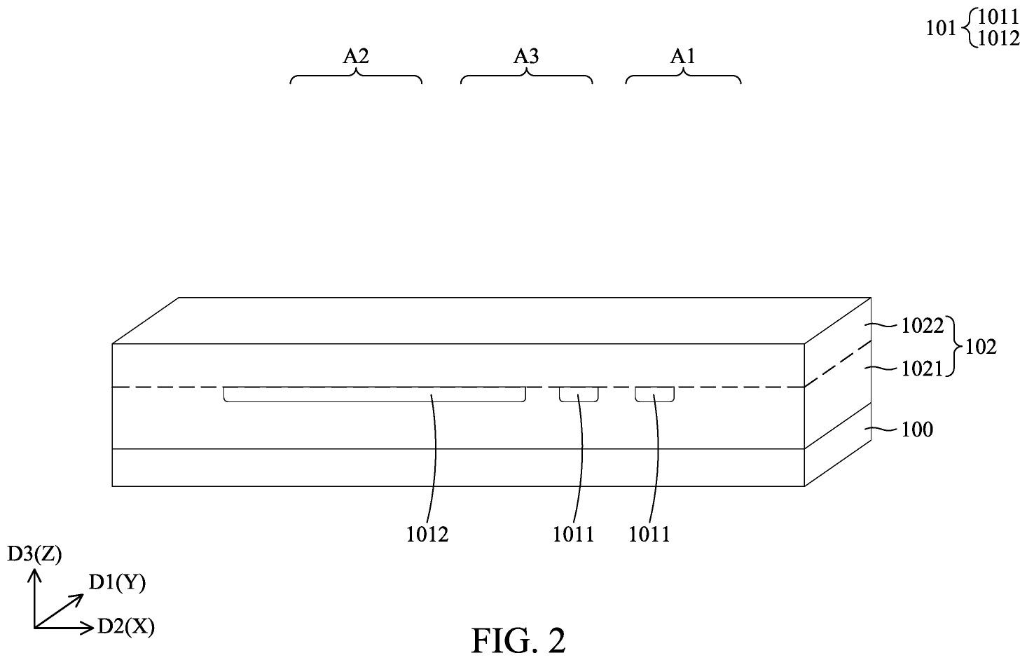

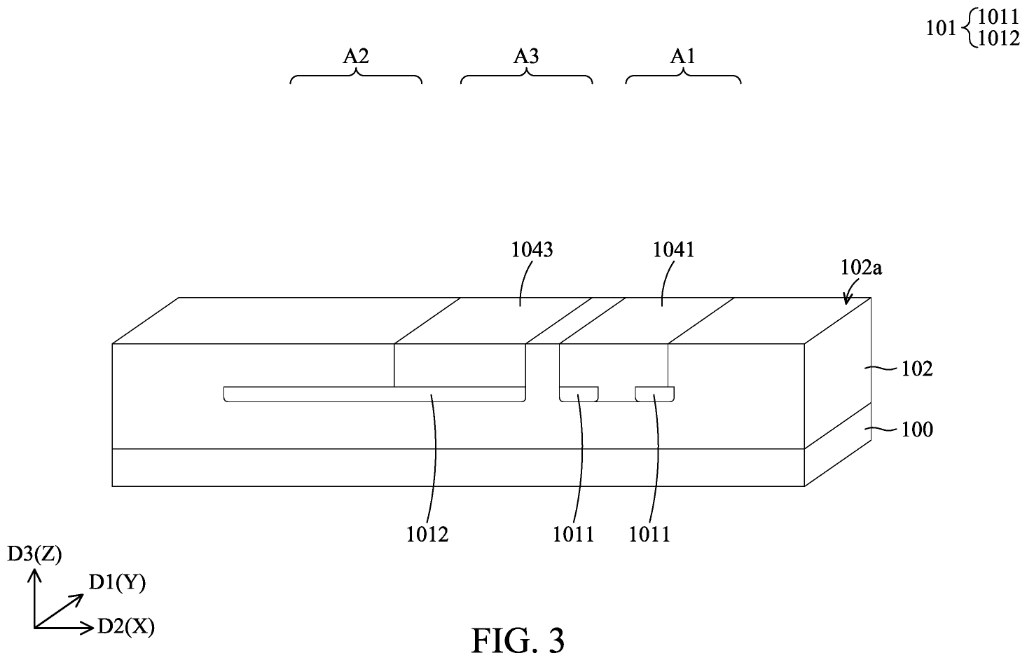

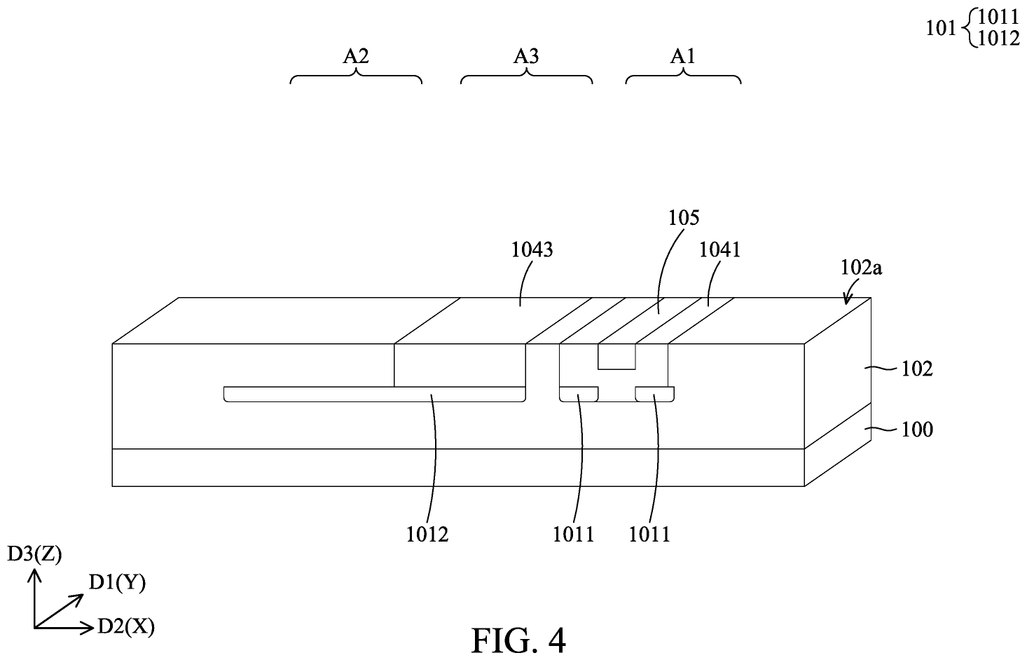

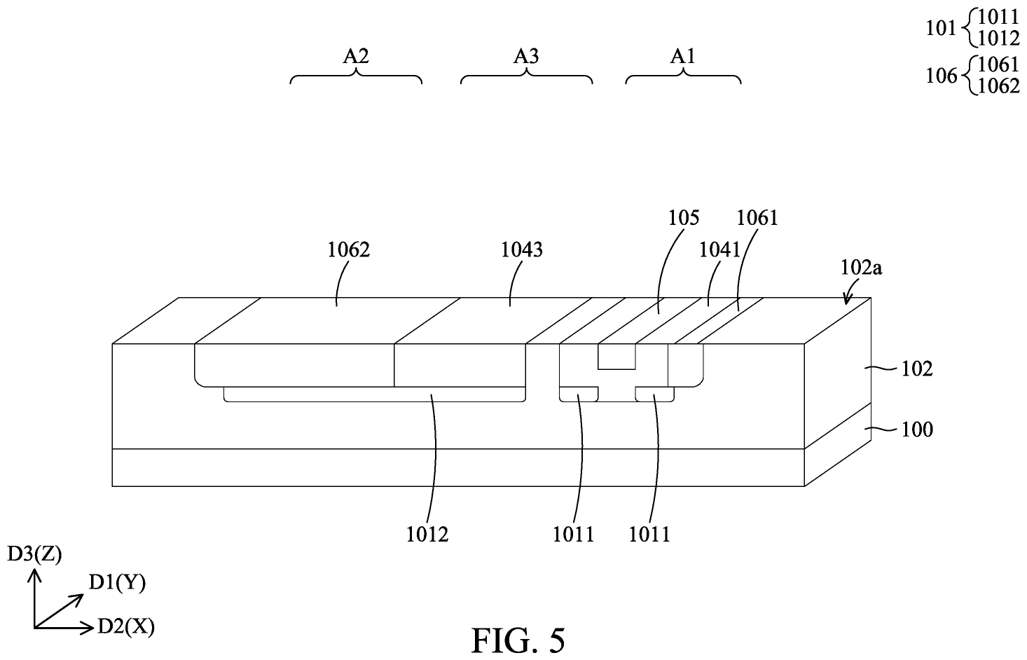

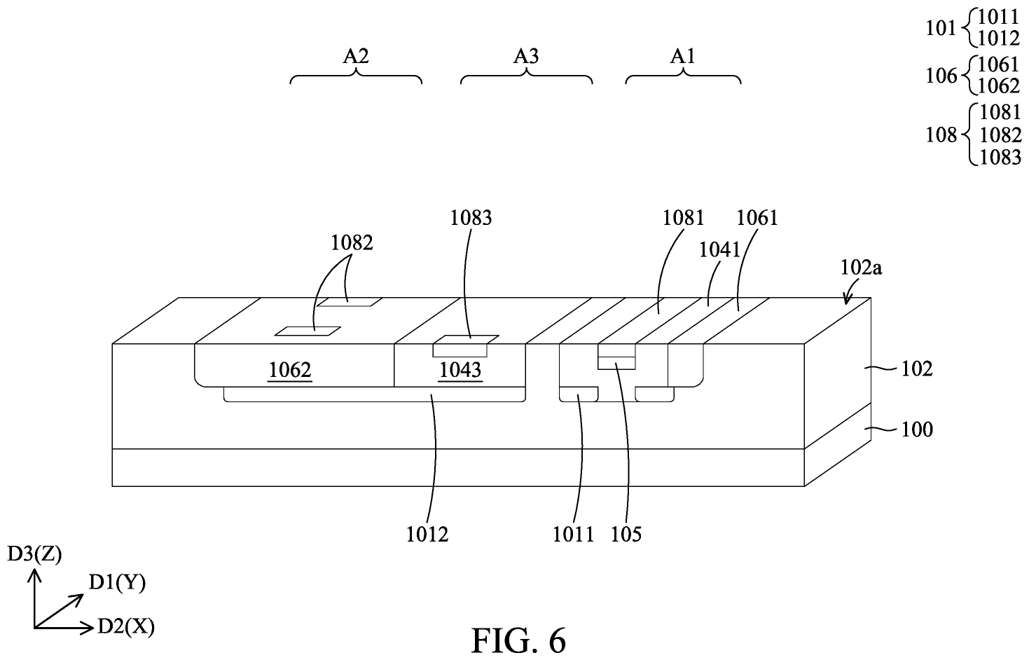

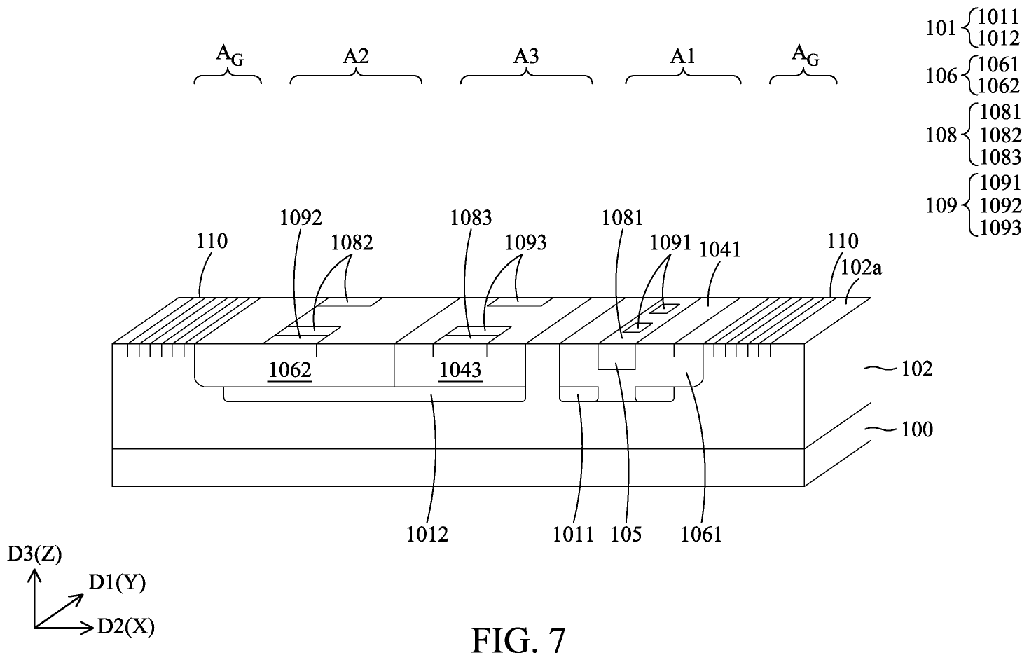

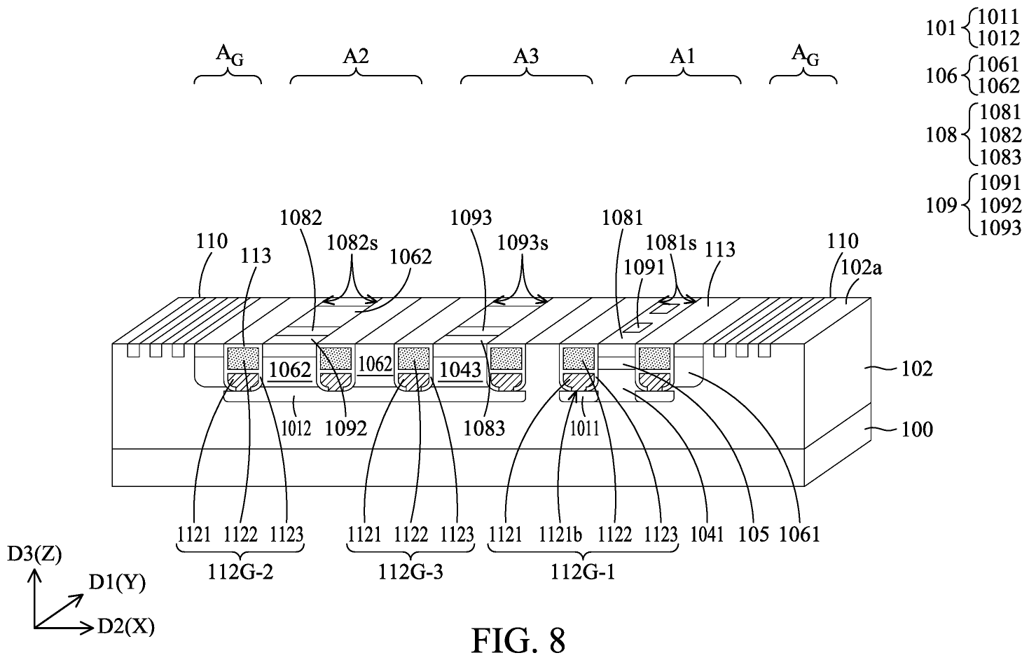

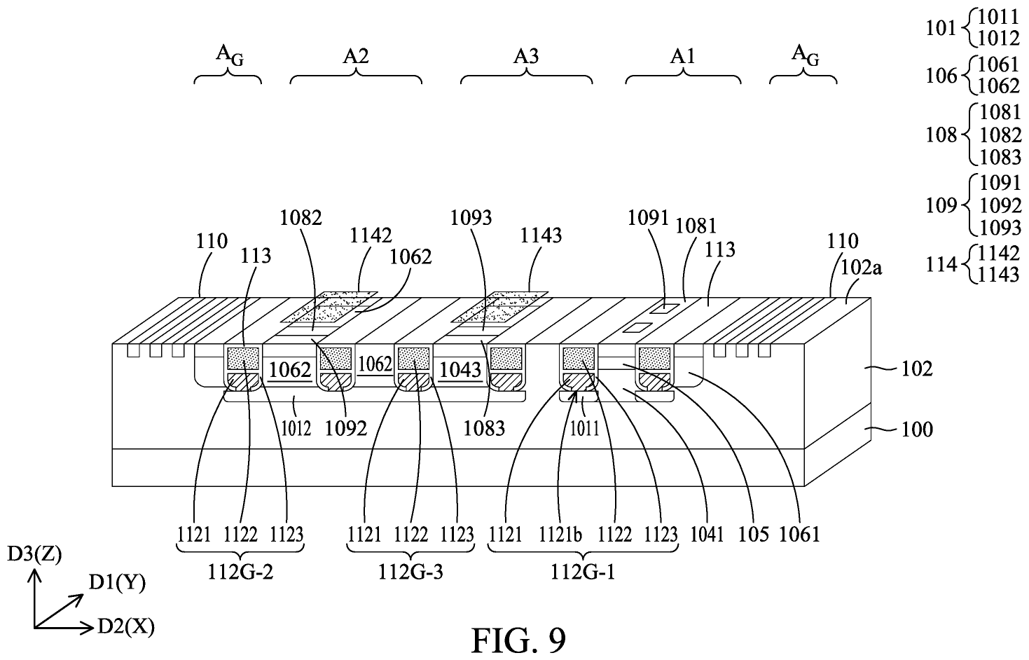

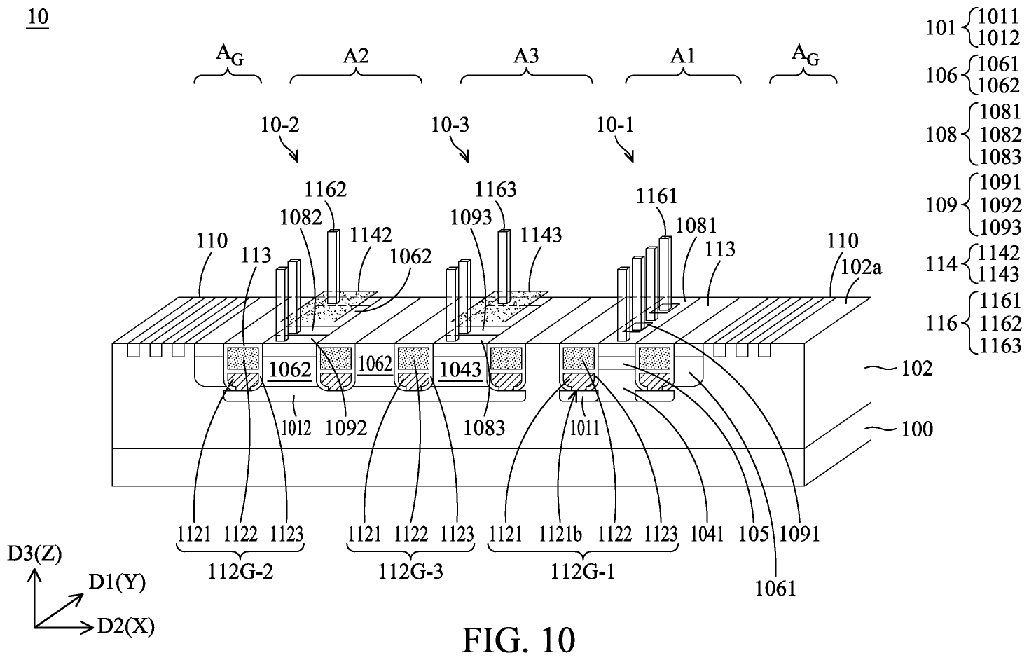

FIG. 1-FIG. 10 illustrate cross-sectional views of intermediate stages of a method for forming a semiconductor device, in accordance with some embodiments of the present disclosure.

Referring to FIG. 1, a substrate 100 that has a first conductivity type is provided according to some embodiments. In some embodiments, the substrate 100 is a bulk semiconductor substrate, such as a semiconductor wafer. The substrate 100 may include silicon or another semiconductor material. For example, the substrate 100 is a silicon wafer. In some embodiments, the substrate 100 includes another elemental semiconductor material such as germanium (Ge). In some other embodiments, the substrate 100 includes compound semiconductor, such as silicon carbide, gallium nitride, gallium arsenide, indium arsenide, or indium phosphide. In some embodiments, the substrate 100 includes alloy semiconductor, such as silicon germanium, silicon germanium carbide, gallium arsenide phosphide, indium gallium phosphide, or another suitable alloy semiconductor. In some embodiments, the substrate 100 may also include a silicon-on-insulator (SOI) layer. The SOI substrate can be formed by using an oxygen implanted isolation (SIMOX) process, a wafer bonding process, another suitable method, or a combination thereof. In some embodiments, the substrate 100 includes different semiconductor materials, such as silicon, silicon germanium, silicon carbide and another suitable material.

In the application of a semiconductor device that includes a vertical-diffused metal-oxide-semiconductor (VDMOS) device such as a vertical trench-gate MOSFET device, the substrate 100 may be a wafer that includes dopants of the first conductivity type. The substrate 100 that has the first conductivity type can act as a drain region of the VDMOS device. In addition, in this exemplified embodiment, the first conductivity type is n-type, but the present disclosure is not limited thereto. In some other embodiments, the first conductivity type can be p-type.

Next, an epitaxial growth process is performed to form an epitaxial layer 102 (FIG. 2) on the substrate 100, in accordance with some embodiments of the present disclosure. A shielding layer 101 is formed in the epitaxial layer 102. The shielding layer includes several shielding portions that are separated from each other. The epitaxial layer 102 and the substrate 100 have the same conductivity type. The shielding layer 101 and the epitaxial layer 102 include dopants of the opposite conductivity types. In some embodiments, such as (but not limited to) applications using silicon-based substrates, the epitaxial layer 102 can be formed by a continuous epitaxial growth, and then the dopants can be implanted into the epitaxial layer 102 by an implantation process to form the shielding layer 101. In some embodiments, such as (but not limited to) applications using silicon carbide substrates, the epitaxial growth may be performed in several stages to form the epitaxial layer 102, and the shielding layer 101 may be formed between the growth stages. In this exemplified embodiment, formation of the epitaxial layer 102 includes two stages, and several doping regions can be formed in the epitaxial layer 102 to serve as shielding portions.

In some embodiments, an epitaxial growth process is performed on the top surface 100a of the substrate 100 to form a first epitaxial portion 1021 of the epitaxial layer 102, as shown in FIG. 1. The substrate 100 and the first epitaxial portion 1021 of the epitaxial layer 102 have the same conductivity type, such as the first conductivity type. In this exemplified embodiment, the substrate 100 and the first epitaxial portion 1021 of the epitaxial layer 102 are n-type. In addition, the doping concentration of the first epitaxial portion 1021 of the epitaxial layer 102 is less than the doping concentration of the substrate 100.

In this exemplary embodiment, a first device (such as a VDMOS device) is formed in the first region A1 of the epitaxial layer 102, a second device (such as an NMOS device) is formed in the second region A2 of the epitaxial layer 102, and a third device (such as a PMOS device) is formed in the third region A3. The NMOS device and the PMOS device are electrically connected to form a CMOS device. Accordingly, a semiconductor device that includes the VDMOS device and the CMOS device integrated on the same substrate is formed.

In some embodiments, an ion implantation process is performed in the first epitaxial portion 1021 to form the first shielding portions 1011 in the first region A1 and the second shielding portion 1012 in the second region A2 and the third region A3, after the first epitaxial portion 1021 is formed. In this exemplary embodiment, the first shielding portions 1011 and the second shielding portion 1012 extend in the first direction D1 (such as Y direction). In addition, the first shielding portions 1011 and the second shielding portion 1012 are separated from each other by a distance in the second direction D2 (such as X direction), as shown in FIG. 1.

In some embodiments, the first shielding portions 1011 and the second shielding portion 1012 that are separated from each other and the first epitaxial portion 1021 of the epitaxial layer 102 have different conductivity types. For example, the first shielding portions 1011 and the second shielding portion 1012 have the second conductivity type. In this exemplary embodiment, the first shielding portions 1011 and the second shielding portion 1012 are p-type, and can be referred to as the p-type shielding portions. In some embodiments, the dopants of the first shielding portions 1011 and the second shielding portion 1012 include aluminum (Al) or another suitable material. In some embodiments, the doping concentration of the first shielding portions 1011 and the second shielding portion 1012 may be in a range of about 1E16 atoms/cm³ to about 1E18 atoms/cm³.

Next, referring to FIG. 2, the epitaxial growth continues in the third direction D3 (for example, the Z direction) to grow a second epitaxial portion 1022 on the top surface 1021a of the first epitaxial portion 1021, in accordance with some embodiments of the present disclosure. The second epitaxial portion 1022 covers the shielding layer 101 that includes the first shielding portions 1011 and the second shielding portion 1012. The second epitaxial portion 1022 has the first conductivity type, such as n-type. In this exemplified embodiment, the first epitaxial portion 1021 and the second epitaxial portion 1022 collectively form an epitaxial layer 102. The thickness (in the third direction D3) of the epitaxial layer 102 may be adjusted and determined according to the operation voltage required in the application.

In some embodiments, the aforementioned epitaxial growth process can be performed by using a metal organic chemical vapor deposition (MOCVD) process, a molecular beam epitaxy (MBE) process, a hydride vapor phase epitaxy (HVPE), a liquid phase epitaxy (LPE) process, a chloride vapor phase epitaxy (Cl-VPE) process, another suitable process or a combination thereof to form the epitaxial layer 102.

Next, several doping regions that are required for each of the devices are formed in the epitaxial layer 102, in accordance with some embodiments of the present disclosure.

Referring to FIG. 3, in some embodiments in which a VDMOS device is formed in the first region A1 of the epitaxial layer 102, the first region A1 of the epitaxial layer 102 is implanted with dopants that have the same conductivity type of the epitaxial layer 102, thereby forming a current spreading layer (CSL) 1041. In addition, the current spreading layer 1041 extends downward from the top surface 102a of the epitaxial layer 102 and contacts the first shielding portions 1011. In this exemplary embodiment, the first region A1 of the epitaxial layer 102 includes two first shielding portions 1011 that are separated from each other in the second direction D2. The current spreading layer 1041 also extends between the first shielding portions 1011. As shown in FIG. 3, the bottom surface of the current spreading layer 1041 is substantially coplanar with the bottom surfaces of the first shielding portions 1011, in accordance with some embodiments of the present disclosure.

In this exemplary embodiment, the current spreading layer 1041 has the first conductivity type, such as n-type. In addition, the doping concentration of the current spreading layer 1041 is greater than the doping concentration of the epitaxial layer 102. Accordingly, when the VDMOS device as formed subsequently is operated, the electrons that flow from the source electrode to the drain electrode (i.e., the substrate 100) and pass between the first shielding portions 1011 can be increased, thereby reducing the resistance of the VDMOS device.

In addition, in some embodiments in which a PMOS device is formed in the third region A3 of the epitaxial layer 102, another current spreading layer (CSL) 1043 can be formed in the third region A3 of the epitaxial layer 102. In this exemplary embodiment, the current spreading layer 1043 has the first conductivity type, such as n-type. The current spreading layer 1043 functions as a channel region of the PMOS device in the third region A3. In addition, the doping concentration of the current spreading layer 1043 is greater than the doping concentration of the epitaxial layer 102, so that the threshold voltage of the PMOS device that is formed subsequently can be improved. In this exemplary embodiment, the current spreading layer 1043 extends downward from the top surface 102a of the epitaxial layer 102 and contacts the second shielding portion 1012.

The current spreading layers 1041 and 1043 can be formed in the same process, in accordance with some embodiments of the present disclosure. For example, the dopants of the first conductivity type (such as n-type) may be simultaneously implanted into the regions that correspond to the current spreading layers 1041 and 1043 of the epitaxial layer 102 by an ion implantation process.

According to some embodiments, the above-mentioned current spreading layers 1041 and 1043 may be formed by using a deposition process, a lithographic patterning process, an etching process, and an implantation process. In one exemplary embodiment, an oxide hard mask material layer (not shown) may be deposited over the top surface 102a of the epitaxial layer 102, and then a patterned photoresist (not shown) is formed on the oxide hard mask material layer. The patterned photoresist includes patterns that correspond to the positions of the current spreading layers 1041 and 1043. Next, the oxide hard mask material layer is etched by using the patterned photoresist as a mask to form a patterned oxide hard mask. Next, the patterned photoresist is removed, and the patterned oxide hard mask remains on the epitaxial layer 102. An ion implantation process is performed on the epitaxial layer 102 through the patterned oxide hard mask to form the current spreading layers 1041 and 1043 in the epitaxial layer 102. Next, the patterned oxide hard mask is removed.

Referring to FIG. 4, in some embodiments, a body region 105 is formed in the current spreading layer 1041 that is formed in the first region A1. The body region 105 extends downward from the top surface 102a of the epitaxial layer 102. In addition, the body region 105 extends in the current spreading layer 1041. For example, the body region 105 extends in the first direction D1. In addition, the body region 105 and the current spreading layer 1041 have different conductivity types, in accordance with some embodiments of the present disclosure.

In this exemplary embodiment, the dopants that have the second conductivity type, such as p-type dopants, are implanted at the current spreading layer 1041 to form the body region 105. In addition, the position of the body region 105 substantially corresponds to the upper position between the two adjacent first shielding portions 1011. The bottom surface of the body region 105 is separated from the top surface of the first shielding portion 1011 by a distance in the third direction D3. In addition, the above-mentioned body region 105 can be formed by a deposition process, a lithographic patterning process, an etching process and an implantation process as described above, in accordance with some embodiments of the present disclosure.

Referring to FIG. 5, in some embodiments, several well regions 106 are formed in the epitaxial layer 102. The depth of each of the well regions 106 is greater than the depth of the body region 105. For example, a well region 1061 is formed in the first region A1 of the epitaxial layer 102, and the well region 1061 extends downward from the top surface 102a of the epitaxial layer 102 to connect one of the first shielding portions 1011. Similarly, another well region 1062 is formed in the second region A2 of the epitaxial layer 102, and the well region 1062 extends downward from the top surface 102a of the epitaxial layer 102 to connect the second shielding portion 1012.

In addition, the well region 1061 and the well region 1062 include dopants of the opposite conductivity type than the epitaxial layer 102, in accordance with some embodiments of the present disclosure. The dopants that have second conductive type, such as p-type dopants, can be implanted into the epitaxial layer 102 by an implantation process to form the well regions 1061 and 1062. In this exemplary embodiment, the well region 1061 in the first region A1 is positioned adjacent to the current spreading layer 1041, and the well region 1062 in the second region A2 is positioned adjacent to the current spreading layer 1042, as shown in FIG. 5. In addition, in this exemplary embodiment, the well region 1062 that has second conductive type (such as p-type) can act as a channel region of the NMOS device (e.g., the second device) that is formed in the second region A2.

Next, several heavily doped portions that are required for the devices formed in each of the regions (such as the first region A1, the second region A2 and the third region A3) are formed in the substrate 100, in accordance with some embodiments of the present disclosure. The heavily doped portions include several first heavily doped portions 108 and several second heavily doped portions 109. The first heavily doped portions 108 and the second heavily doped portions 109 have different conductivity types. The heavily doped portions function as the source regions, the drain regions and the bulk regions of the to-be-formed devices (such as the VDMOS device and the CMOS device that includes the NMOS device and the PMOS device).

Referring to FIG. 6, in some embodiments, several first heavily doped portions 108 that have the first conductivity type are simultaneously formed by using ion implantation process, in accordance with some embodiments of the present disclosure. For example, the dopants of the first conductivity type are simultaneously implanted into the body region 105, the current spreading layer 1043 and the well region 1062 to form the first heavily doped portions 108. As shown in FIG. 6, the first heavily doped portions 108 include the first heavily doped portions 1081, 1082 and 1083. In this exemplary embodiment, the first heavily doped portions 108 and the epitaxial layer 102 have the same conductivity type, such as the first conductivity type (e.g., n-type).

Specifically, in some embodiments in which a VDMOS device is formed in the first region A1, a first heavily doped portion 1081 that has the first conductivity type (such as n-type) is formed in the body region 105. The first heavily doped portion 1081 can be referred to as a source region of the VDMOS device. The first heavily doped portion 1081 not only extends downward from the top surface 102a of the epitaxial layer 102, but also extends in the first direction D1. In addition, the depth of the first heavily doped portion 1081 in the vertical direction (such as in the third direction D3) is less than the depth of the body region 105 in the vertical direction (such as in the third direction D3).

In addition, in some embodiments in which a NMOS device is formed in the second region A2, two first heavily doped portions 1082 that have the first conductivity type (such as n-type) are formed in the well region 1062. The first heavily doped portions 1082 can be referred to as a source region and a drain region of the NMOS device. The first heavily doped portions 1082 extend downward from the top surface 102a of the epitaxial layer 102 and are separated from each other in the first direction D1. In addition, the depth of the first heavily doped portions 1082 in the vertical direction (such as in the third direction D3) is less than the depth of the well region 1062 in the vertical direction (such as in the third direction D3).

In addition, in some embodiments in which a PMOS device is formed in the third region A3, a first heavily doped portion 1083 that has the first conductivity type (such as n-type) is formed in the current spreading layer 1043. The first heavily doped portion 1083 can be referred to as a bulk region of the PMOS device. This bulk region may be adjacent to a subsequently formed source region (such as one of the second heavily doped portions 1093 in FIG. 7) of the PMOS device.

Details of the manufacturing method of the above-mentioned first heavily doped portions 108 are similar to the above-mentioned descriptions of the current spreading layer 1041, the current spreading layer 1043 and the well region 1062, and will not be repeated here. In some embodiments, the doping concentration of each of the first heavily doped portions 108 is greater than the doping concentration of each of the current spreading layers 1041 and 1043. In some embodiments, the doping concentration of each of the first heavily doped portions 108 is in a range of about 1E18 atoms/cm³ to about 1E21 atoms/cm³.

Next, referring to FIG. 7, several second heavily doped portions 109 that are required for each of the devices in the respective regions are formed by using ion implantation process, in accordance with some embodiments of the present disclosure. For example, the dopants of the second conductivity type are simultaneously implanted into the first heavily doped portion 1081 (i.e., can be referred to the source region 1081 of the first device), the current spreading layer 1043 and the well region 1062 to form the second heavily doped portions 109. In this exemplary embodiment, the second heavily doped portions 109 and the shielding portions 101 have the same conductivity type, such as the second conductivity type (e.g., p-type).

Specifically, in some embodiments in which a VDMOS device is formed in the first region A1, two second heavily doped portions 1091 that have the second conductivity type (such as p-type) are formed in the source region (i.e. the first heavily doped portion 1081). The second heavily doped portions 1091 function as the bulk regions of the VDMOS device. It should be noted that the second heavily doped portions 1091 in the source region (i.e. the first heavily doped portion 1081) extend downward and are in contact with the underlying body region 105 although this is not shown in FIG. 7. Accordingly, in this exemplary embodiment, the depth of the second heavily doped portions 1091 in the vertical direction (such as in the third direction D3) is substantially equal to the depth of the first heavily doped portion 1081 in the vertical direction (such as in the third direction D3).

In addition, in some embodiments in which a NMOS device is formed in the second region A2, a second heavily doped portion 1092 that has the second conductivity type (such as p-type) is formed in the well region 1062. The second heavily doped portion 1092 can be referred to as a bulk region of the NMOS device. In this exemplary embodiment, the second heavily doped portion 1092 that functions as the bulk region of the NMOS device is adjacent to the first heavily doped portion 1082 that functions as the source region of the NMOS device, as shown in FIG. 7.

In addition, in some embodiments in which a PMOS device is formed in the third region A3, two second heavily doped portions 1093 that have the second conductivity type (such as p-type) are formed in the current spreading layer 1043. In this exemplary embodiment, the second heavily doped portions 1093 can be referred to as a source region and a drain region of the PMOS device. In this exemplary embodiment, the second heavily doped portion 1093 that functions as the source region of the PMOS device is adjacent to the first heavily doped portion 1083 that functions as the bulk region of the PMOS device, as shown in FIG. 7.

In addition, the semiconductor device further includes several guard rings 110 at the periphery of the regions where the devices are formed (e.g., the first region A1, the second region A2 and the third region A3), in accordance with some embodiments of the present disclosure. For example, dopants of the second conductivity type are implanted into the epitaxial layer 102 by ion implantation process for forming guard rings 110 in the peripheral region AG of the epitaxial layer 102. The guard rings 110 can prevent the manufactured devices from being affected by noise.

The above-mentioned second heavily doped portions 109 and the guard rings 110 can be formed in the same process, and have substantially the same ion implantation depth. Details of the manufacturing methods of the above-mentioned second heavily doped portions 109 and the guard rings 110 are similar to the above-mentioned descriptions of the current spreading layer 1041, the current spreading layer 1043 and the well region 1062, and will not be repeated here. In some embodiments, the doping concentration of each of the second heavily doped portions 109 and the guard rings 110 is greater than the doping concentration of the shielding portions 101. In some embodiments, the doping concentration of each of the second heavily doped portions 109 is in a range of about 1E18 atoms/cm³ to about 1E21 atoms/cm³. In some embodiments, the doping concentration of each of the guard rings 110 is in a range of about 1E18 atoms/cm³ to about 1E21 atoms/cm³.

After the above-mentioned first heavily doped portions 108, the second heavily doped portions 109 and the guard rings 110 are formed, a high-temperature annealing process is performed to activate the dopants in every regions or layers, in accordance with some embodiments of the present disclosure. After the high-temperature annealing process, the junctions of these doped regions and/or doped layers and/or doped portions in the epitaxial layer 102 are finalized. The temperature of the annealing process depends on the actual material selected for forming the substrate 100. In embodiments that use a silicon-based substrate 100, a high-temperature annealing process may be performed at a temperature in a range of about 1000° C. to about 1200° C. In embodiments that use a silicon carbide substrate 100, the high-temperature annealing process may be performed at a temperature in a range of about 1600° C. to about 1700° C. It should be noted that the numerical values of the annealing temperature are provided for illustrative purposes, and the embodiments of the present disclosure are not limited thereto.

Next, referring to FIG. 8, the trench gate structures of each device are formed in each of the regions, in accordance with some embodiments of the present disclosure. In this exemplary embodiment, the first trench gate structures 112G-1 of the first device (e.g., the VDMOS device) are formed in the first region A1, and the second gate structures 112G-2 of the second device (e.g., the NMOS device) are formed in the second region A2. In addition, the trench gate structures 112G-3 of the third device (e.g., the PMOS device) are formed in the third region A3.

In some embodiments, the trench gate structures of all devices of the semiconductor device are fabricated simultaneously. Specifically, the first trench gate structures 112G-1, the second trench gate structures 112G-2 and the third trench gate structures 112G-3 are formed in the same process to simplify the manufacture process of the semiconductor device, in accordance with some embodiments of the present disclosure. In this exemplary embodiment, the trench gate structures extend downward from the top surface 102a of the epitaxial layer 102 into the epitaxial layer 102. In addition, in some embodiments, the trench gate structures that are formed in the epitaxial layer 102 are split-trench gate structures.

As shown in FIG. 8, in some embodiments in which a VDMOS device with trench gates are formed in the first region A1, each of the first trench gate structures 112G-1 includes a bottom conductive portion 1121 and a top conductive portion 1122 over the bottom conductive portion 1121. The first trench gate structure 112G-1 further includes an insulating layer 1123 that electrically isolates the bottom conductive portion 1121 from the top conductive portion 1122. The insulating layer 1123 covers the sidewalls of the bottom conductive portion 1121 and the top conductive portion 1122. In addition, the insulating layer 1123 extends between the bottom conductive portion 1121 and the top conductive portion 1122 to electrically isolate the bottom conductive portion 1121 from the top conductive portion 1122.

In addition, the two first trench gate structures 112G-1 extend in the first direction D1 and are separated from each other in the second direction D2, in accordance with some embodiments of the present disclosure. The first heavily doped portion 1081, the second heavily doped portions 1091 and the body region 105 are positioned between the two first trench gate structures 112G-1. In this exemplary embodiment, the opposite sidewalls 1081s of the first heavily doped portion 1081 and the opposite sidewalls of the body region 105 are in contact with the insulating layers 1123 of the first trench gate structures 112G-1.

It should be noted that the bottoms of the first trench gate structures 112G-1 are in contact with the first shielding portions 1011, in accordance with some embodiments of the present disclosure. More specifically, the bottom conductive portions 1121 of the first trench gate structures 112G-1 are in direct contact with (or in physical contact with) the first shielding portions 1011. Accordingly, the bottom conductive portions 1121 of the first trench gate structures 112G-1 are electrically connected to the first shielding portions 1011. In addition, in some embodiments, the bottom conductive portions 1121 of the first trench gate structures 112G-1 are electrically connected to the source region (i.e., the first heavily doped portion 1081) of the first device (such as a VDMOS device).

The above-mentioned first trench gate structures 112G-1 may be formed by (but not limited to) a deposition process, a lithographic patterning process and an etching process to form the trenches in the current spreading layer 1041 (FIG. 7), in accordance with some embodiments of the present disclosure. Those trenches extend in the first direction D1, and the bottoms of the trenches expose the first shielding portions 1011. Next, an insulating material is formed on the sidewalls and bottom surfaces of the trenches. Portions of the insulating material are then removed by etching back to form the lower portions of the insulating layer 1123 and expose the first shielding portions 1011. Next, a conductive material is deposited in the trenches and then etched back to form the bottom conductive portions 1121. The bottom surfaces 1121b of the bottom conductive portions 1121 are in direct contact with the first shielding portions 1011. Next, an insulating material can be deposited again in the remaining spaces of the trenches to form the upper portions of the insulating layer 1123 on the upper sidewalls of the trenches and the bottom conductive portions 1121. In this exemplary embodiment, the upper portions of the insulating layer 1123 cover the bottom conductive portions 1121. Next, the top conductive portions 1122 can be formed above the bottom conductive portions 1121 by depositing another conductive material and etching back the conductive material. The top conductive portions 1122 are separated from the bottom conductive portions 1121 by the insulating layer 1123. In addition, in this exemplary embodiment, the top conductive portions 1122 are relatively recessed in the trenches. A capping layer 113 (for example, including an oxide material or another suitable insulating material) is deposited on each of the top conductive portions 1122 to cover the top conductive portion 1122. In some embodiments, the top surfaces of the capping layers 113 are substantially coplanar with the top surface 102a of the epitaxial layer 102.

In some embodiments, the bottom conductive portions 1121 include polysilicon, titanium, titanium nitride, another suitable conductive material or a combination of the aforementioned materials. The top conductive portions 1122 may include polysilicon or another suitable conductive material. In addition, the bottom conductive portions 1121 and the top conductive portions 1122 may include the same conductive material or different conductive materials. In some embodiments, the insulating layer 1123 includes silicon oxide, another suitable semiconductor oxide material or a combination of the aforementioned materials. In addition, the insulating layer 1123 may be formed by a deposition process, an oxidation process, another suitable process or a combination of the aforementioned processes. In embodiments wherein the epitaxial layer 102 includes silicon carbide, the sidewalls and the bottom surfaces of the trenches that include silicon carbide can be oxidized by a high-temperature process (for example, using a high-temperature furnace tube) to form silicon oxide. The silicon oxide layer that is on the sidewall and the bottom surface of each of the trenches can be referred to as a portion of the insulating layer 1123 in the trench. In addition, an oxide layer, for example, may be deposited on the bottom conductive portions 1121 to cover the top surfaces of the bottom conductive portions 1121 so that the subsequently formed top conductive portions 1122 can be electrically isolated from the bottom conductive portions 1121.

In addition, in some embodiments in which a NMOS device is formed in the second region A2 and a PMOS device is formed in the third region A3, the second trench gate structures 112G-2 and the third trench gate structures 112G-3 have the same configuration as the first trench gate structures 112G-1, as shown in FIG. 8. In this exemplary embodiment, each of the second trench gate structures 112G-2 and the third trench gate structures 112G-3 includes a bottom conductive portion 1121 and a top conductive portion 1122 over the bottom conductive portion 1121. In addition, in this exemplary embodiment, each of the second trench gate structures 112G-2 and the third trench gate structures 112G-3 further includes an insulating layer 1123 that electrically isolates the bottom conductive portion 1121 from the top conductive portion 1122. Details of the materials and the manufacturing method of the above-mentioned second trench gate structures 112G-2 and the third trench gate structures 112G-3 are similar to the above-mentioned descriptions of the above-mentioned first trench gate structures 112G-1, and they will not be repeated here.

In addition, in this exemplary embodiment, the second trench gate structures 112G-2 and the third trench gate structures 112G-3 extend in the first direction D1 and are separated from each other in the second direction D2. The first heavily doped portions 1082, the second heavily doped portion 1092 and the well region 1062 in the second region A2 are positioned between the two second trench gate structures 112G-2. In addition, the opposite sidewalls of the first heavily doped portions 1082, the opposite sidewalls of the second heavily doped portion 1092 and the opposite sidewalls of the well region 1062 are in contact with the second trench gate structures 112G-2. For example, the opposite sidewalls 1082s of the first heavily doped portions 1082 are in contact with the insulating layers 1123 of the second trench gate structures 112G-2, as shown in FIG. 8. Similarly, the first heavily doped portion 1083, the second heavily doped portions 1093 and the current spreading layer 1043 in the third region A3 are positioned between the two third trench gate structures 112G-3. The opposite sidewalls of the first heavily doped portion 1083, the opposite sidewalls of the second heavily doped portions 1093 and the opposite sidewalls of the current spreading layer 1043 are in contact with the third trench gate structures 112G-3. For example, the opposite sidewalls 1093s of the second heavily doped portions 1093 are in contact with the insulating layers 1123 of the third trench gate structures 112G-3, as shown in FIG. 8.

It should be noted that the bottoms of the second trench gate structures 112G-2 and the third trench gate structures 112G-3 are in contact with the second shielding portion 1012, in accordance with some embodiments of the present disclosure. More specifically, in this exemplary embodiment, the bottom conductive portion 1121 of each of the second trench gate structures 112G-2 and the third trench gate structures 112G-3 is in direct contact (or in physical contact) with the second shielding portion 1012. Therefore, the bottom conductive portions 1121 of the second trench gate structures 112G-2 and the third trench gate structures 112G-3 are electrically connected to the second shielding portion 1012.

The first shielding portions 1011 and the second shielding portion 1012 of the shielding layer 101 are formed by using the same manufacturing process, in accordance with some embodiments of the present disclosure. Therefore, the first shielding portions 1011 and the second shielding portion 1012 may be positioned at the same horizontal level and have substantially the same depth (in the third direction D3) in the epitaxial layer 102. In addition, the above-mentioned first trench gate structures 112G-1, the second trench gate structures 112G-2 and the third trench gate structures 112G-3 are formed by using the same manufacturing process, and those trench gate structures extend downward to the underlying shielding portions, in accordance with some embodiments of the present disclosure. Therefore, the first trench gate structures 112G-1, the second trench gate structures 112G-2 and the third trench gate structures 112G-3 have approximately the same vertical depth in the epitaxial layer 102.

Next, referring to FIG. 9, the planar gate structures 114 are further formed in the regions in which the non-vertical type devices are fabricated, in accordance with some embodiments of the present disclosure. For example, a planar gate structure 1142 of the second device (e.g., an NMOS device) is formed in the second region A2, and another planar gate structure 1143 of the third device (e.g., a PMOS device) is formed in the third region A3.

In some embodiments, the top conductive portions 1121 of the second trench gate structures 112G-2 in the second region A2 are electrically connected to the planar gate structure 1142. In addition, the bottom conductive portions 1121 of the second trench gate structures 112G-2 are electrically connected to the underlying second shielding portion 1012.

In some embodiments, the top conductive portions 1121 of the third trench gate structures 112G-3 in the third region A3 are electrically connected to the planar gate structure 1143. In addition, the bottom conductive portions 1121 of the third trench gate structures 112G-3 are electrically connected to the underlying second shielding portion 1012.

In some embodiments, each of the planar gate structures 1142 and 1143 includes a gate dielectric layer and a gate electrode that is formed on the gate dielectric layer. To simplify the drawings, the gate dielectric layers of the planar gate structures 1142 and 1143 are omitted in FIG. 9 for the sake of simplicity and clarity. That is, only the gate electrodes of the planar gate structures 1142 and 1143 are shown in FIG. 9 for the clarity of the drawings.

The above-mentioned gate dielectric layers may include silicon oxide, another suitable dielectric material or a combination of the aforementioned materials. The above-mentioned gate electrodes may include polycrystalline silicon, another suitable conductive material or a combination of the aforementioned materials. In one exemplary embodiment, a dielectric material layer (not shown) is formed on the epitaxial layer 102 by a deposition process (such as a physical vapor deposition (PVD) process, a chemical vapor deposition (CVD) process, an atomic layer deposition (ALD) process) or a thermal oxidation process. A conductive material (not shown) is then deposited on the dielectric material layer by a deposition process, such as a physical vapor deposition (PVD) process, a chemical vapor deposition (CVD) process, or another suitable process. Next, the dielectric material layer and the conductive material are patterned using a lithography process and an etching process to form the gate dielectric layers and gate electrodes of the planar gate structures 1142 and 1143.

In addition, in some embodiments in which a NMOS device is formed in the second region A2, the first heavily doped portions 1082 that are referred to as the source region and the drain region are separated from each other in the first direction D1. The first heavily doped portions 1082 are positioned on opposite sides of the planar gate structure 1142, as shown in FIG. 9. More specifically, the two second trench gate structures 112G-2 are separated from each other in the second direction D2. The planar gate structure 1142 and the first heavily doped portions 1082 (functioning as the source region and the drain region) are positioned between the second trench gate structures 112G-2. In this exemplary embodiment, the first heavily doped portions 1082 extend between the second trench gate structures 112G-2. For example, the opposite sidewalls 1082s of the first heavily doped portions 1082 are in contact with the second trench gate structures 112G-2. In some embodiments, one set of opposite sidewalls of the planar gate structure 1142 extends in the first direction D1. The other set of opposite sidewalls of the planar gate structure 1142 correspond to the first heavily doped portions 1082 that function as the source region and the drain region of the NMOS device.

Accordingly, the second device (such as an NMOS device) that is formed in the second area A2 includes not only the planar gate structure 1142 but also the second trench gate structures 112G-2, in accordance with some embodiments of the present disclosure. Therefore, one or more non-vertical semiconductor devices that are integrated with the first device (such as a VDMOS device) each have multiple gates and multiple channels, in accordance with some embodiments of the present disclosure. For example, a tri-gate structure of the second device (such as an NMOS device) is depicted in the drawings. The tri-gate structure includes two second trench gate structures 112G-2 and one planar gate structure 1142. Thus, in this exemplary embodiment, the second device (such as an NMOS device) has three channels.

Similarly, in some embodiments in which the third device (such as a PMOS device) is formed in the third region A3, the third device includes the planar gate structure 1143 and the third trench gate structures 112G-3. Therefore, the third device that is integrated with the first device (such as a VDMOS device) has multiple gates and multiple channels, in accordance with some embodiments of the present disclosure. For example, a tri-gate structure (that includes two third trench gate structures 112G-3 and one planar gate structure 1143) of the third device is depicted in the drawings. Thus, in this exemplary embodiment, the third device (such as an PMOS device) has three channels.

Next, referring to FIG. 10, an interlayer dielectric (ILD) layer is formed over the epitaxial layer 102 after the planar gate structures 1142 and 1143 are formed, in accordance with some embodiments of the present disclosure. The interlayer dielectric (ILD) layer covers the epitaxial layer 102, the first heavily doped portions 108, the second heavily doped portions 109, the well region 1062, the guard rings 110, the first trench gate structures 112G-1, the second trench gate structures 112G-2, the third trench gate structures 112G-3, the planar gate structures 1142 and 1143. Next, several contact plugs 116 are formed in the interlayer dielectric (ILD) layer, in accordance with some embodiments of the present disclosure.

To illustrate the configurations and positions of the planar gate structures 114 clearly, the contact plugs 116 and the underlying doped regions, the gate dielectric layers of the planar gate structures 1142 and 1143 and the interlayer dielectric (ILD) layer are omitted in FIG. 10. That is, only the gate electrodes of the planar gate structures 1142 and 1143 are shown in FIG. 10 for the sake of simplicity and clarity.

In some embodiments, the interlayer dielectric (ILD) layer includes silicon oxide, another suitable dielectric material (such as low-k dielectric material), or a combination of the aforementioned materials. In some embodiments, the material of the interlayer dielectric (ILD) layer is different from the material of the insulating layers 1123 of the trench gate structures. In some other embodiments, the interlayer dielectric (ILD) layer and the insulating layers 1123 of the trench gate structures include the same material. In addition, an interlayer dielectric layer may be deposited on the epitaxial layer 102 using a deposition process. In some embodiments, the deposition process may include a physical vapor deposition (PVD) process, a chemical vapor deposition (CVD) process, another suitable process, or a combination of the aforementioned processes.

Next, portions of the interlayer dielectric (ILD) layer are removed by a lithography process and an etching process to form several contact holes (not shown), in accordance with some embodiments of the present disclosure. The bottoms of the contact holes expose the respective conductive portions below, such as the source regions, the drain regions and the body regions. In some embodiments, the aforementioned lithographic patterning process includes photoresist coating (e.g., spin-on coating), soft baking, mask alignment, exposure, post-exposure baking, photoresist developing, rinsing and drying (e.g., hard baking), another suitable process or a combination of the foregoing processes. In some embodiments, the aforementioned etching process includes a dry etching process, a wet etching process, a plasma etching process, a reactive ion etching process, another suitable process, or a combination of the foregoing processes.

Next, the contact holes in each of the region are filled with one or more suitable conductive materials to form the contact plugs 116, in accordance with some embodiments of the present disclosure.

In some embodiments, the contact plugs 1161 of the first device 10-1 (such as a VDMOS device) that is formed in the first region A1 are electrically connected to the first heavily doped portion 1081 (source region) and the second heavily doped portions 1091 (bulk regions), as shown in FIG. 10. In some embodiments, the source electrode of the first device 10-1 is electrically connected to the body electrode of the first device 10-1 since the second heavily doped portions 1091 are in contact with the underlying body region 105. When the first device 10-1 is operated, the first heavily doped portion 1081 (source region) and the second heavily doped portions 1091 (body regions) are equipotential. In other words, the contact plugs 1161 of the first device 10-1 are all electrically connected to the source region.

In addition, in some embodiments, some of the contact plugs 1162 of the second device 10-2 (such as an NMOS device) that is formed in the second region A2 are electrically connected to the first heavily doped portions 1082 (e.g., including n+ dopants) that function as the source region and the drain region. At least one of the contact plugs 1162 is electrically connected to the second heavily doped portion 1092 (e.g., including p+ dopants) that functions as the bulk region. In some embodiments, the source electrode of the second device 10-2 is electrically connected to the bulk electrode of the second device 10-2 since the second heavily doped portion 1092 (i.e. the bulk region) is in contact with the adjacent first heavily doped portion 1082 (i.e. the source region). Therefore, when the second device 10-2 is operated, the first heavily doped portion 1082 that functions as the source region and the second heavily doped portion 1092 that functions as the bulk region are equipotential, in accordance with some embodiments of the present disclosure.

Similarly, in some embodiments, one of the contact plugs 1163 of the third device 10-3 (such as a PMOS device) that is formed in the third region A3 is electrically connected to the first heavily doped portion 1083 (e.g., including n+ dopants) that functions as the bulk region. Some of the contact plugs 1163 are electrically connected to the second heavily doped portions 1093 (e.g., including p+ dopants) that function as the source region and the drain region. In some embodiments, the source electrode of the third device 10-3 is electrically connected to the bulk electrode of the third device 10-3 since the first heavily doped portion 1083 (that functions as the bulk region of the PMOS device) is in contact with the adjacent second heavily doped portion 1093 (that functions as the source region of the PMOS device). Therefore, when the third device 10-3 is operated, the second heavily doped portion 1093 that functions as the source region and the first heavily doped portion 1083 that functions as the bulk region are equipotential, in accordance with some embodiments of the present disclosure.

In addition, each of the contact plugs 116 is a single-layer structure or a multilayer structure. In some embodiments, each of the contact plugs 116 may include a contact barrier layer and a contact conductive layer. The contact barrier layer may be formed on the sidewall and the bottom portion of the contact hole as a barrier liner. The contact conductive layer fills up the remaining space in the contact hole. In this exemplary embodiment, the contact plugs 116 with single-layer structure are depicted in FIG. 10 for the purpose of simplicity and clarity. In addition, in some embodiments, the top surfaces of the contact plugs 116 (for example, including the top surfaces of the contact barrier layers and the top surfaces of the contact conductive layers) are substantially level with the top surface of the interlayer dielectric (ILD) layer (not shown).

In some exemplary embodiments, a barrier material (not shown) can be formed on the interlayer dielectric (ILD) layer by using a deposition process, and the barrier material is isotropically deposited in the contact holes. Then, a conductive material (not shown) is deposited on the barrier material layer, and the conductive material fills up the remaining space in the contact holes. Next, in some embodiments, the excess portions of the conductive material and barrier material that are above the top surface of the interlayer dielectric layer are removed, such as by etching or another suitable method, to form the contact barrier layers and the contact conductive layers in the contact holes. Accordingly, the above-mentioned contact plugs 116 in some embodiments can be formed in the interlayer dielectric (ILD) layer.

In some embodiments, the material of the contact barrier layers of the contact plugs 116 may include titanium (Ti), titanium nitride (TiN), tantalum (Ta), tantalum nitride (TaN), cobalt (Co), cobalt tungsten phosphorus compound (CoWP), ruthenium (Ru), aluminum oxide (Al₂O₃), magnesium oxide (MgO), aluminum nitride (AlN), tantalum pentoxide (Ta₂O₅), silicon dioxide (SiO₂), hafnium dioxide (HfO₂), zirconium dioxide (ZrO₂), magnesium fluoride (MgF₂), calcium fluoride (CaF₂), another suitable barrier material, or a combination of the aforementioned materials. In some embodiments, the contact barrier layers can be formed by a chemical vapor deposition (CVD) process, an atomic layer deposition (ALD) process, a physical vapor deposition (PVD) process, another suitable process, or a combination of the foregoing processes.

In some embodiments, each of the contact conductive layers of the contact plugs 116 is a single-layer structure or a multilayer structure that includes one or more conductive materials. In some embodiments, the material of the contact conductive layers includes tungsten (W), aluminum (Al), copper (Cu), titanium (Ti), tantalum (Ta), titanium nitride (TiN), tantalum nitride (TaN), nickel silicide (NiSi), cobalt silicide (CoSi), tantalum carbide (TaC), tantalum silicon nitride (TaSiN), tantalum carbide nitride (TaCN), titanium aluminide (TiAl), titanium aluminide nitride (TiAlN), another suitable metal, or a combination of the foregoing materials. In addition, the aforementioned conductive material can be formed by using a chemical vapor deposition (CVD) process, an atomic layer deposition (ALD) process, a physical vapor deposition (PVD) process, another suitable process, or a combination of the foregoing processes, in accordance with some embodiments of the present disclosure.

In some embodiments, the contact plugs 116 for all of the devices that are integrated in the semiconductor device 10 are formed simultaneously. For example, the contact plugs 1161 of the first device 10-1 (such as a VDMOS device) in the first region A1, the contact plugs 1162 of the second device 10-2 (such as an NMOS device) in the second region A2 and the contact plugs 1163 of the third device 10-3 (such as a PMOS device) t in the third region A3 are formed in the same process to simplify the manufacture of the semiconductor device 10, in accordance with some embodiments of the present disclosure.

Next, after the contact plugs 116 are formed, the subsequent processes for forming other components of the semiconductor device 10 are performed. According to some embodiments, a metal layer (not shown) is formed over the interlayer dielectric layer (not shown) and the contact plugs 116. The metal layer covers the contact plugs 116 and is in physical and electrical contact with the contact plugs 116. Therefore, the metal layer is electrically connected to the first heavily doped portions 108, the second heavily doped portions 109, the body region 105 and the well region 1062 through the contact plugs 116, in accordance with some embodiments of the present disclosure.

In some embodiments, the above-mentioned metal layer includes copper, silver, gold, aluminum, tungsten, another suitable metal material, or a combination of the aforementioned materials. In some embodiments, the metal layer and the contact plugs 116 are formed of the same material(s). In some other embodiments, the material of the metal layer is different from the material of the contact plugs 116. The metal layer can be formed on the contact plugs 116 by a deposition process, in accordance with some embodiments of the present disclosure. The foregoing deposition process may include a physical vapor deposition (PVD) process, a chemical vapor deposition (CVD) process, another suitable process, or a combination of the aforementioned processes. In some embodiments, after the metal layer is formed, the fabrication of the semiconductor device 10 is substantially completed.

According to some embodiments, the semiconductor device 10 may include the first device 10-1 such as a VDMOS element, the second device 10-2 such as an NMOS element, and the third device 10-3 such as a PMOS device. The NMOS device and the PMOS device that are electrically connected to each other form a complementary metal-oxide-semiconductor (CMOS) device. In addition, the CMOS device acts as a switching device that controls the VDMOS device to turn on or turn off the operation of the VDMOS device, in accordance with some embodiments of the present disclosure. In a non-limiting exemplary embodiment in which a CMOS device is provided, the drain electrode of the NMOS device and the drain electrode of the PMOS device are connected to each other, and the gate electrode of the VDMOS device is electrically connected to the drain electrode of the CMOS device.

According to the aforementioned descriptions, the semiconductor device and method for forming the same, in accordance with some embodiments of the present disclosure, are provided. The devices with different driving current flow directions may be integrated on the same substrate to form the semiconductor device. In some exemplary embodiments, a VDMOS device that has a driving current flowing in the vertical direction and a CMOS device that has a driving current flowing in the horizontal direction (which can also be referred to as the planar direction) are formed on the same substrate of the semiconductor device. In high-power device applications, the VDMOS device is a high-power device, and the CMOS device can be used as a driver for the VDMOS device. The semiconductor device of the embodiments has many advantages. For example, in the conventional semiconductor device, several devices of different functions are typically integrated in a package manner that produces excessive parasitic inductance. Compared to the conventional semiconductor device, the integrated (monolithic) semiconductor device proposed in the embodiments can effectively reduce the parasitic inductance between the drive circuits of the VDMOS device and the CMOS device (i.e. acting as a control device). The reduction of parasitic inductance can increase the operating frequency of the entire circuit or the entire system. In addition, in some embodiments in which the epitaxial growth of silicon carbide is provided in the manufacture of the semiconductor device (e.g., growing the epitaxial layer on the substrate), the semiconductor device can be operated at a higher temperature.

In addition, each of the devices that are integrated in the semiconductor device includes a split-trench gate structure, in accordance with some embodiments of the present disclosure. For the VDMOS device of the semiconductor device of the embodiment, the split-trench gates of the first trench gate structures 112G-1 can reduce the gate-to-drain parasitic capacitance, thereby increasing the switching speed of the VDMOS device. For the CMOS device of the semiconductor device of the embodiment, the second trench gate structures 112G-2 and the third trench gate structures 112G-3 are fabricated simultaneously with the first trench gate structures 112G-1, thereby simplifying the manufacturing process and increasing the number of channels of the CMOS device. For example, in the above-mentioned exemplary embodiment, the NMOS device formed in the second region A2 and the PMOS device formed in the third region A3 each have three gate electrodes and three channels. Compared to the conventional CMOS device with a planar gate, the CMOS device of the embodiments has more channels in the same area, thereby increasing the channel density. When the CMOS device of the embodiments is operated, more current is generated, thus increasing the operation speed.

In addition, the shielding layer 101 of the semiconductor device, in accordance with some embodiments of the present disclosure, can provide a good protection effect for the integrated devices. For example, the first shielding portions 1011 that are formed in the first region A1 are positioned at the bottom of the first trench gate structures 112G-1 of the VDMOS device, which can prevent the insulating layers in the trench gate structures from being damaged by high-intensity electric fields. For example, the second shielding portion 1012 that is formed in the second region A2 and the third region A3 is positioned under the CMOS device and covers the bottoms of the well regions and the trench gate structures of the CMOS device (including the second trench gate structures 112G-2 and the third trench gate structures 112G-3). Thus, the second shielding portion 1012 serves as a good isolation layer for the CMOS device in the epitaxial layer 102, in accordance with some embodiments of the present disclosure.

In addition, the conventional planar-type CMOS device (without trench gate structure) is provided with pins on the top surface of the epitaxial layer, and the electric charges accumulated in the isolation layer that is embedded in the epitaxial layer can only flow out through the well region between the isolation layer and the surface pins. That is, there is no conductor directly connecting the isolation layer and the surface pins. Thus, the conventional planar-type CMOS device has a longer flow path for passing the accumulated charges, thus having a weaker ability to remove the accumulated charges. According to some embodiments of the present disclosure, the bottoms (e.g., the bottom conductive portions 1121) of the trench gate structures of each of the devices (such as the first trench gate structures 112G-1, the second trench gate structures 112G-2 and the third trench gate structures 112G-3) of the semiconductor device are in direct contact with the shielding layer 101. Therefore, the trench gate structures are electrically connected to the shielding layer 101. In some embodiments, the shielding layer 101 includes dopants of the second conductivity type (such as p-type), and can be grounded via a connection wire (not shown). Therefore, when the semiconductor device of the embodiment is operated, the electric charges that are accumulated in the bottom conductive portions 1121 can be quickly released since the shielding layer 101 is in direct contact with the bottom conductive portions 1121. That is, the semiconductor device has better ability to release charges and prevent interference of accumulated charges, in accordance with some embodiments of the present disclosure.

According to the manufacturing method proposed in some embodiments, as described in the above-mentioned steps, many components of different devices that are formed in different regions, such as a CMOS device and a VDMOS device, can be fabricated simultaneously. For example, related components of the first device (such as a VDMOS device) that is formed in the first region A1, the second device (such as an NMOS device) that is formed in the second region A2 and the third device (such as a PMOS device) that is formed in the third region A3 can be formed simultaneously. The semiconductor device of the embodiments can be fabricated by slightly modifying the process steps. For example, two extra masks are added to form the well region 1062 of the NMOS device (FIG. 5) and the planar gate structures 114 of the NMOS device and the PMOS device (FIG. 9), in accordance with some embodiments of the present disclosure. Therefore, the semiconductor device of the embodiments has a simple manufacturing process and is compatible with existing manufacturing processes.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate that has a first conductivity type;
an epitaxial layer on the substrate, wherein the epitaxial layer has the first conductivity type;
a first device, comprising:
a first trench gate structure that extends downward from a top surface of the epitaxial layer into the epitaxial layer, wherein the substrate functions as a drain region of the first device; and
a first shielding portion that is positioned below the first trench gate structure and in contact with a bottom portion of the first trench gate structure, wherein the first shielding portion has a second conductivity type; and
a second device that is separated from the first device and electrically connected to the first device, wherein the second device comprises:
a second trench gate structure that extends downward from the top surface of the epitaxial layer into the epitaxial layer;
a planar gate structure that is formed over the top surface of the epitaxial layer; and
a second shielding portion that is positioned under the second trench gate structure and in contact with a bottom portion of the second trench gate structure, wherein the second shielding portion has the second conductivity type.

2. The semiconductor device as claimed in claim 1, wherein the first trench gate structure and the second trench gate structure are split-trench gate structures, and each of the split-trench gate structures comprises:
a bottom conductive portion;
a top conductive portion over the bottom conductive portion; and
an insulating layer that covers sidewalls of the bottom conductive portion and sidewalls of the top conductive portion, wherein the insulating layer extends between the bottom conductive portion and the top conductive portion to electrically isolate the bottom conductive portion from the top conductive portion.

3. The semiconductor device as claimed in claim 2, wherein the bottom conductive portion of the first trench gate structure is in physical contact with the first shielding portion and electrically connected to the first shielding portion; and
the bottom conductive portion of the second trench gate structure is in physical contact with the second shielding portion and electrically connected to the second shielding portion.

4. The semiconductor device as claimed in claim 1, wherein the first trench gate structure and the second trench gate structure have the same vertical depth in the epitaxial layer.

5. The semiconductor device as claimed in claim 1, wherein the first shielding portion and the second shielding portion are positioned at the same horizontal level.

6. The semiconductor device as claimed in claim 1, wherein the first trench gate structure and the second trench gate structure extend in a first direction, and the first device and the second device are separated from each other in a second direction, wherein the second direction is different from the first direction, and the second device further comprises:
a source region and a drain region that correspond to opposite sides of the planar gate structure, wherein the source region and the drain region are separated from each other in the first direction.

7. The semiconductor device as claimed in claim 6, wherein the second device includes two second trench gate structures that are separated from each other in the second direction, wherein the planar gate structure, the source region and the drain region are positioned between the two second trench gate structures, and
wherein one set of opposite sidewalls of the planar gate structure extends in the first direction, and the other set of opposite sidewalls of the planar gate structure corresponds to the source region and the drain region and extends between the two second trench gate structures.

8. The semiconductor device as claimed in claim 1, wherein the first device further comprises:
a current spreading layer that is formed in the epitaxial layer and in contact with the first shielding portion, wherein the current spreading layer has the first conductivity type, and a doping concentration of the current spreading layer is greater than a doping concentration of the epitaxial layer;
a body region that is formed in the current spreading layer and extends downward from the top surface of the epitaxial layer, wherein the body region has the second conductivity type; and
a first heavily doped portion that is formed in the body region and extends downward from the top surface of the epitaxial layer,
wherein the first heavily doped portion has the first conductivity type and acts as a source region of the first device.

9. The semiconductor device as claimed in claim 8, wherein the first device includes two first trench gate structures that are separated from each other in the second direction and two first shielding portions that are under the two first trench gate structures,
wherein the current spreading layer extends between the two first trench gate structures, and a bottom surface of the current spreading layer is coplanar with bottom surfaces of the two first shielding portions.

10. The semiconductor device as claimed in claim 1, wherein the second device further includes:
a well region that extends downward from the top surface of the epitaxial layer to contact the second shielding portion, a sidewall of the well region is in contact with the second trench gate structure, and the well region has the second conductivity type, wherein the planar gate structure is positioned above the well region; and
first heavily doped portions that are formed in the well region and extend downward from the top surface of the epitaxial layer, wherein the first heavily doped portions have the first conductivity type and act as a source region and a drain region of the second device.

11. The semiconductor device as claimed in claim 1, further comprising:
a third device that is separated from the first device, wherein the third device is electrically connected to the second device, and the third device comprises:
a third trench gate structure that extends downward from the top surface of the epitaxial layer into the epitaxial layer.

12. The semiconductor device as claimed in claim 11, wherein the second shielding portion that is under the second trench gate structure extends continuously to a position that is under the third trench gate structure, and the second shielding portion is in direct contact with the third trench gate structure,
wherein the second shielding portion is electrically connected to the third trench gate structure.

13. The semiconductor device as claimed in claim 12, wherein the third device further comprises:
a current spreading layer that is formed in the epitaxial layer and in contact with the second shielding portion, wherein the current spreading layer has the first conductivity type, and a doping concentration of the current spreading layer is greater than a doping concentration of the epitaxial layer; and
second heavily doped portions that extend downward from the top surface of the epitaxial layer, wherein the second heavily doped portions have the second conductivity type and act as a source region and a drain region of the third device.

14. The semiconductor device as claimed in claim 13, wherein the second shielding portion is in direct contact with a bottom surface of the current spreading layer and covers the bottom surface of the current spreading layer.

15. The semiconductor device as claimed in claim 11, wherein the second device is an NMOS device, the third device is a PMOS device, and the second device and the third device form a complementary metal-oxide-semiconductor (CMOS) device,
wherein the CMOS device acts as a switching device that controls the first device.

16. A method for forming a semiconductor device, comprising:
providing a substrate that has a first conductivity type;
forming an epitaxial layer on the substrate, wherein the epitaxial layer has the first conductivity type;
forming a first device in a first region of the epitaxial layer and forming a second device in a second region of the epitaxial layer, wherein the second device is separated from the first device and electrically connected to the first device, and
wherein the first device comprises:
a first trench gate structure that extends downward from a top surface of the epitaxial layer into the epitaxial layer, wherein the substrate functions as a drain region of the first device; and
a first shielding portion that is positioned below the first trench gate structure and in contact with a bottom portion of the first trench gate structure, wherein the first shielding portion has a second conductivity type; and
wherein the second device comprises:
a second trench gate structure that extends downward from the top surface of the epitaxial layer into the epitaxial layer;
a planar gate structure that is formed over the top surface of the epitaxial layer; and
a second shielding portion that is positioned under the second trench gate structure and in contact with a bottom portion of the second trench gate structure, wherein the second shielding portion has the second conductivity type.

17. The method for forming a semiconductor device as claimed in claim 16, wherein the first shielding portion and the second shielding portion are formed in the same process.

18. The method for forming a semiconductor device as claimed in claim 16, wherein the first trench gate structure and the second trench gate structure are formed in the same process.

19. The method for forming a semiconductor device as claimed in claim 16, wherein after the first shielding portion and the second shielding portion are formed, the method further comprises:
forming a current spreading layer in the first region, wherein the current spreading layer is formed in the epitaxial layer and extends downward from the top surface of the epitaxial layer to connect the first shielding portion, wherein the current spreading layer has the first conductivity type, and a doping concentration of the current spreading layer is greater than a doping concentration of the epitaxial layer;
forming a body region in the current spreading layer, wherein the body region extends downward from the top surface of the epitaxial layer, and the body region has the second conductivity type; and
forming a well region in the second region, wherein the well region extends downward from the top surface of the epitaxial layer to contact the second shielding portion.

20. The method for forming a semiconductor device as claimed in claim 19, wherein after the current spreading layer, the body region and the well region are formed, the method further comprises:
forming first heavily doped portions simultaneously in the body region that is positioned in the first region and in the well region that is positioned in the second region, wherein the first heavily doped portions have the first conductivity type and act as a source region of the first device and a drain region and a source region of the second device; and
forming second heavily doped portions simultaneously in the body region that is positioned in the first region and in the well region that is positioned in the second region, wherein the second heavily doped portions have the second conductivity type and act as bulk regions of the first device and the second device.

21. The method for forming a semiconductor device as claimed in claim 20, wherein after the current spreading layer, the body region, the well region, the first heavily doped portions and the second heavily doped portions are formed, the first trench gate structure is formed in the first region and the second trench gate structure is formed in the second region.

22. The method for forming a semiconductor device as claimed in claim 16, wherein the first trench gate structure and the second trench gate structure are split-trench gate structures.

23. The method for forming a semiconductor device as claimed in claim 16, further comprising:
forming a third device in a third region of the epitaxial layer, wherein the third device is separated from the first device and electrically connected to the second device,
wherein the second shielding portion that is under the second trench gate structure extends continuously to the third region.

24. The method for forming a semiconductor device as claimed in claim 23, wherein the third device further comprises:
a third trench gate structure that extends downward from the top surface of the epitaxial layer into the epitaxial layer,
wherein a bottom portion of the third trench gate structure is in contact with the second shielding portion.

25. The method for forming a semiconductor device as claimed in claim 24, wherein the first trench gate structure, the second trench gate structure and the third trench gate structure are formed in the same process.
